(19) United States
(12) Patent Application Publication
(10) Pub. No.: US 2025/0366331 A1
(43) Pub. Date: Nov. 27, 2025

(54) DISPLAY PANEL AND DISPLAY DEVICE

(71) Applicant: Wuhan Tianma Microelectronics Co., Ltd., Wuhan (CN)

(72) Inventor: Yaqin LUO, Wuhan (CN)

(21) Appl. No.: 19/271,725

(22) Filed: Jul. 16, 2025

Related U.S. Application Data
(63) Continuation of application No. PCT/CN2024/104142, filed on Jul. 8, 2024.

(30) Foreign Application Priority Data
May 21, 2024 (CN) 202410636006.1

(51) Int. Cl. H10K 59/131; H10D 86/40; H10D 86/60; H10K 59/121; H10K 59/35

(52) U.S. Cl. CPC H10K 59/131; H10K 59/1213; H10K 59/353; H10D 86/441; H10D 86/60

(57) ABSTRACT

Provided are a display panel and a display device. The display panel includes pixel circuits including a driving transistor and a first transistor. The driving transistor is electrically connected to the first transistor. The display panel further includes a substrate, an array layer and an organic light-emitting layer. The organic light-emitting layer includes a first electrode layer, an organic layer, and a second electrode layer. The first electrode layer includes a first electrode. Along a direction perpendicular to a plane of the display panel, the first electrode overlaps with at least part of the first transistor; and the array layer includes a first power signal line overlapping with at least part of the first transistor. Poor brightness stability of the display panel is improved, synchronously blocking the first transistors in different pixel circuits is achieved, and color cast problem of the display panel at a large angle is solved.

### CROSS-REFERENCE TO RELATED APPLICATION

This application is a continuation of International Application No. PCT/CN2024/104142, filed on Jul. 8, 2024, which claims priority to Chinese Patent Application No. 202410636006.1, filed on May 21, 2024. All of the aforementioned applications are hereby incorporated by reference in their entireties.

### TECHNICAL FIELD

The present disclosure relates to the field of display technologies, and in particular, to a display panel and a display device.

### BACKGROUND

The OLED (Organic Light-Emitting Diode) display screen has advantages such as low power consumption, low cost, self-luminescence, wide viewing angle and fast response, and is the focus of research in the display field currently. When applied to a display panel, a pixel circuit is designed to provide a driving current for an OLED to drive the OLED to emit light, and changing of the driving current has an obvious influence on the light-emitting brightness of the OLED.

However, in an existing display panel, a thin film transistor device in the pixel circuit is prone to characteristic drift and changes in leakage current when exposed to light, leading to poor brightness stability of the display panel and affecting the display quality.

### SUMMARY

In view of this, embodiments of the present disclosure provide a display panel and a display device to solve the above-mentioned problems.

In a first aspect, an embodiment of the present disclosure provides a display panel including pixel circuits including a driving transistor and a first transistor. The driving transistor is electrically connected to the first transistor. The display panel further includes a substrate, an array layer and an organic light-emitting layer. The organic light-emitting layer includes a first electrode layer, an organic layer, and a second electrode layer. The first electrode layer includes a first electrode. Along a direction perpendicular to a plane of the display panel, the first electrode overlaps with at least part of the first transistor; and the array layer includes a first power signal line overlapping with at least part of the first transistor.

In a second aspect, an embodiment of the present disclosure provides a display device including the display panel described in the first aspect.

In the embodiments of the present disclosure, the first electrode and the first power signal line are provided to overlap with at least part of the first transistor, thereby reducing the exposure of the first transistor to external ambient light, alleviating an influence of the large leakage current of the first transistor on the gate potential of the driving transistor, improving the poor brightness stability of the display panel, and thus improving the display effect.

At the same time, since the first electrode and the first power supply signal line are located in different layers, the first electrode and the first power supply signal line can cooperatively block the first transistor, thereby avoiding the space limitation of overlapping with the first transistor by a same layer, avoiding the external light at a relatively large angle from entering the first transistor, and thus further helping the leakage current problem of the first transistor. Moreover, the first electrode and the first power signal line may block the first transistors in different pixel circuits, thereby synchronously blocking the first transistors in different pixel circuits, making it possible for the brightness changes of sub-pixels of different colors to be consistent, and thus avoiding the large-angle color cast of the display panel. In addition, the blocking degree of the first transistors in different pixel circuits by the first electrode and the first power signal line may be flexibly adjusted as required, to meet different display requirements of the display panel.

### BRIEF DESCRIPTION OF DRAWINGS

FIG. 1 is a schematic plane diagram of a display panel according to an embodiment of the present disclosure;

FIG. 2 is a schematic diagram of a pixel circuit in FIG. 1;

FIG. 3 is a schematic cross-sectional view of a display panel according to an embodiment of the present disclosure;

FIG. 4 is a schematic layout diagram of a display panel according to an embodiment of the present disclosure;

FIG. 5 is a schematic layout diagram of another display panel according to an embodiment of the present disclosure;

FIG. 6 is a schematic layout diagram of another display panel according to an embodiment of the present disclosure;

FIG. 7 is a schematic layout diagram of another display panel according to an embodiment of the present disclosure;

FIG. 8 is a schematic layout diagram of another display panel according to an embodiment of the present disclosure;

FIG. 9 is a schematic layout diagram of another display panel according to an embodiment of the present disclosure;

FIG. 10 is a schematic layout diagram of another display panel according to an embodiment of the present disclosure;

FIG. 11 is a schematic layout diagram of another display panel according to an embodiment of the present disclosure;

FIG. 12 is a schematic layout diagram of another display panel according to an embodiment of the present disclosure;

FIG. 13 is a schematic layout diagram of another display panel according to an embodiment of the present disclosure;

FIG. 14 is a schematic layout diagram of another display panel according to an embodiment of the present disclosure;

FIG. 15 is a schematic layout diagram of another display panel according to an embodiment of the present disclosure;

FIG. 16 is a schematic diagram of an optical path related to an embodiment of the present disclosure;

FIG. 17 is a schematic layout diagram of another display panel according to an embodiment of the present disclosure;

FIG. 18 is an enlarged view of region Q in FIG. 17;

FIG. 19 is a schematic plan diagram of another display panel according to an embodiment of the present disclosure;

FIG. 20 is a schematic cross-sectional view of the display panel shown in FIG. 19;

FIG. 21 is a schematic layout diagram of another display panel according to an embodiment of the present disclosure;

FIG. 22 is a schematic layout diagram of another display panel according to an embodiment of the present disclosure; and

FIG. 23 is a schematic diagram of a display device according to an embodiment of the present disclosure.

### DESCRIPTION OF EMBODIMENTS

In order to better illustrate the technical solutions of the present disclosure, detailed description of embodiments of the present disclosure will be provided below in conjunction with the accompanying drawings.

It should be made clear that the embodiments described are merely part of the embodiments of the present disclosure rather than all of the embodiments. Based on the described embodiments of the present disclosure, all other embodiments obtained by those ordinary skilled in the art without creative efforts shall fall within the protection scope of the present disclosure.

The terms used in the embodiments of the present disclosure are only for the purpose of describing specific embodiments, and are not intended to limit the present disclosure. The singular forms “a/an”, “said”, and “the” used in the embodiments of the present disclosure and the attached claims are also intended to include plural forms thereof, unless noted otherwise.

Through careful and in-depth research, the applicant provides a solution to the problems existing in the related art.

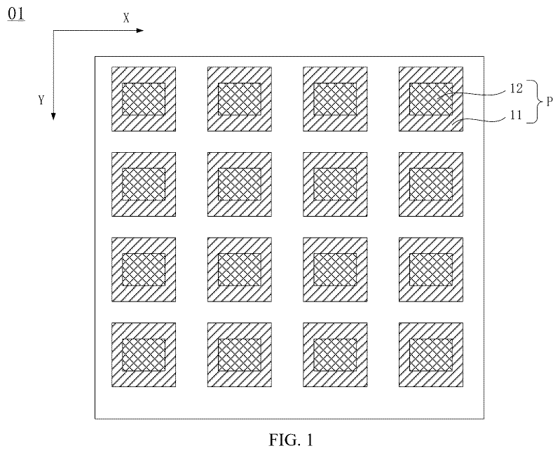

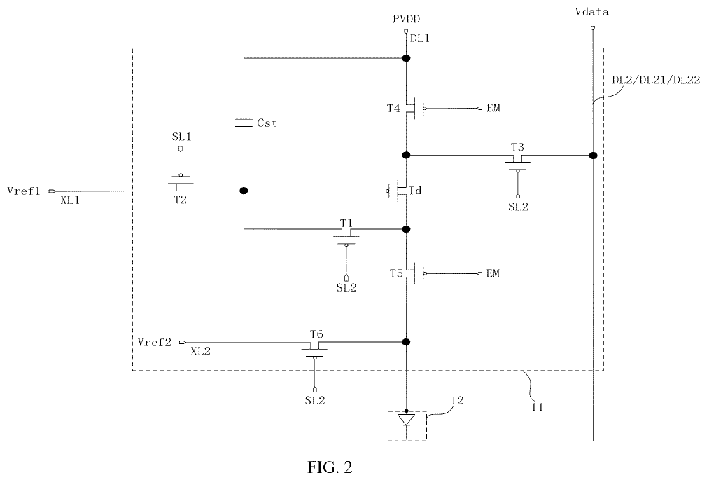

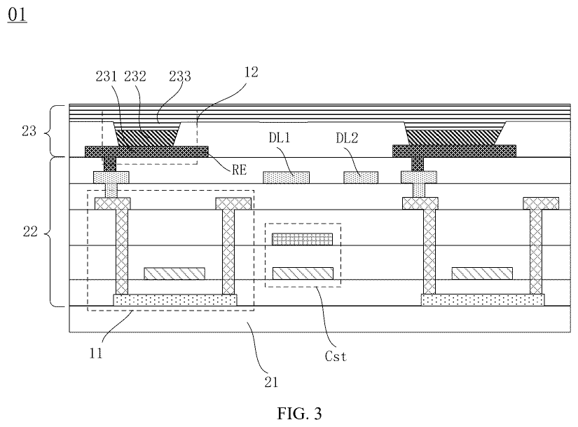

FIG. 1 is a schematic plane diagram of a display panel according to an embodiment of the present disclosure. FIG. 2 is a schematic diagram of a pixel circuit in FIG. 1. FIG. 3 is a schematic cross-sectional view of a display panel according to an embodiment of the present disclosure.

An embodiment of the present disclosure provides a display panel 01, as shown in FIG. 1 and FIG. 2, the display panel 01 includes a pixel circuit 11 and a light emitting device 12 electrically connected to each other, and the pixel circuit 11 is configured to drive the light emitting device 12 to emit light. The pixel circuit 11 includes a driving transistor Td, a threshold compensation transistor M1 and a gate initialization transistor M2. A gate of the driving transistor Td is electrically connected to the threshold compensation transistor M1 and the gate initialization transistor M2 at the first node N1. The driving transistor Td is configured to generate a light-emitting driving current. The threshold compensation transistor M1 is configured to compensate the threshold voltage of the driving transistor Td to the gate of the driving transistor Td. The gate initialization transistor M2 is configured to transmit an initialization signal to the gate of the driving transistor Td. The threshold compensation transistor M1 and the gate initialization transistor M2 may be dual-gate transistors.

As shown in FIG. 3, the display panel 01 further includes a substrate 21, an array layer 22 and an organic light-emitting layer 23. The array layer 22 is located between the substrate 21 and the organic light-emitting layer 23. The transistor in the pixel circuit 11 is located in the array layer 22. The light-emitting device 12 is located in the organic light-emitting layer 23. The light emitting device 12 may be an organic light emitting diode. It should be noted that FIG. 3 only shows one transistor in the pixel circuit 11.

The organic light-emitting layer 23 includes a first electrode layer 231, an organic layer 232 and a second electrode layer 233. The organic layer 232 is located between the first electrode layer 231 and the second electrode layer 233. The first electrode layer 231 is located at a side of the second electrode layer 233 facing the substrate 21. The first electrode layer 231 may be an anode layer of the light-emitting device 12. The organic layer 232 may be a light-emitting material layer of the light-emitting device 12. The second electrode layer 233 may be a cathode layer of the light-emitting device 12.

The first electrode layer 231 includes a first electrode RE. The first electrode RE may be an anode of the light emitting device 12.

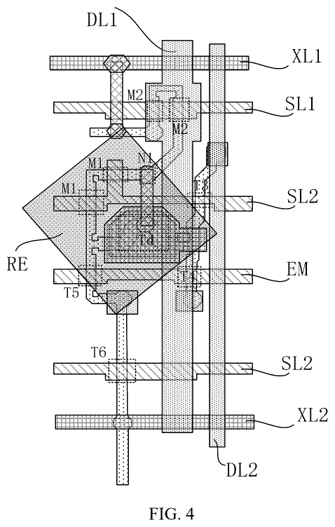

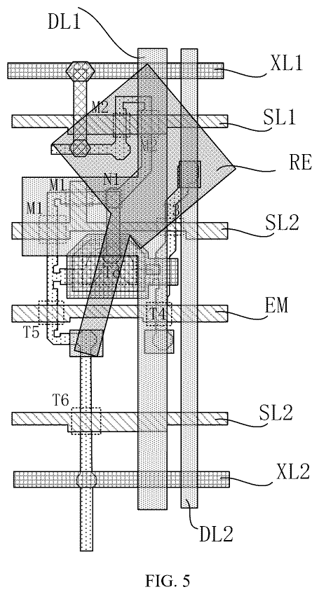

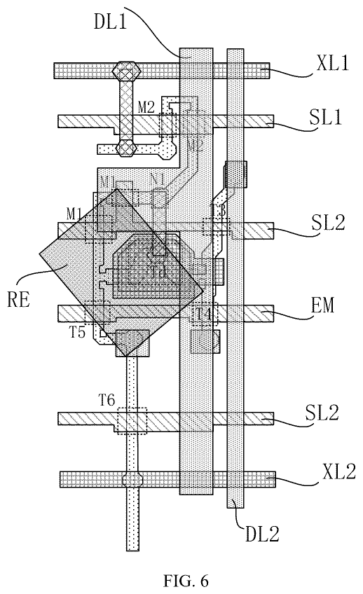

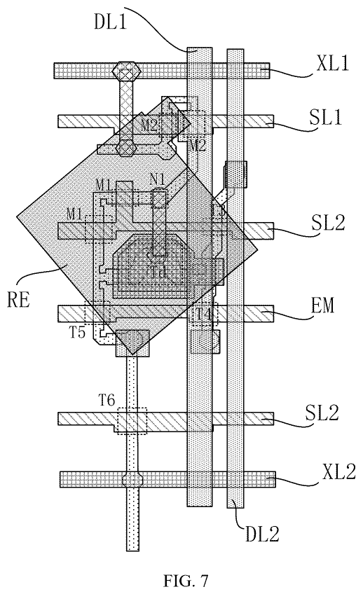

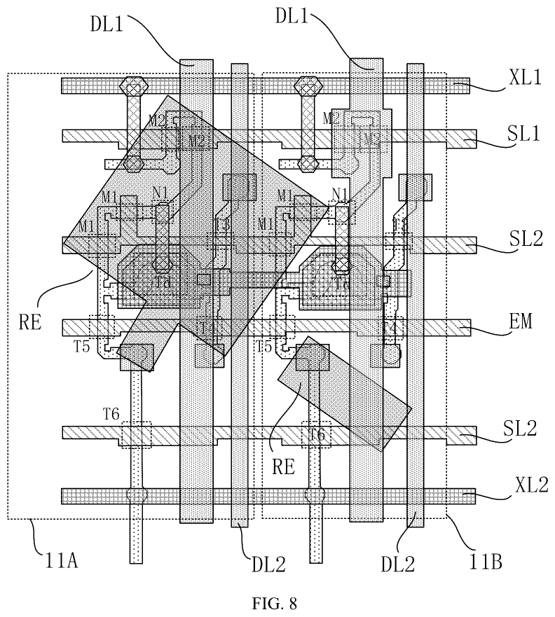

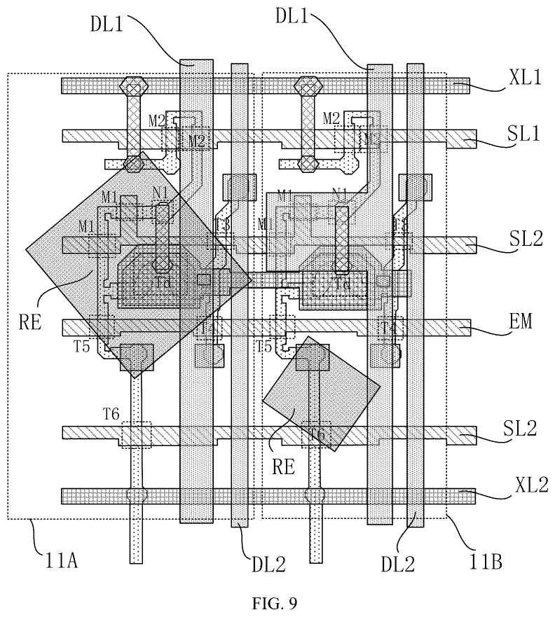

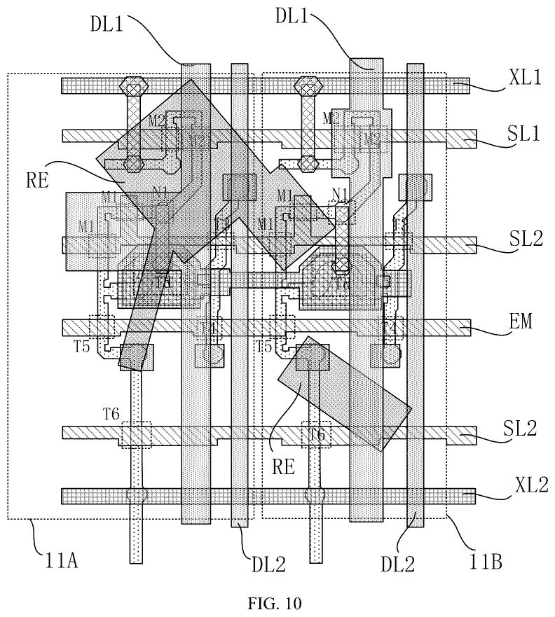

FIG. 4 is a schematic layout diagram of a display panel according to an embodiment of the present disclosure. FIG. 5 is a schematic layout diagram of another display panel according to an embodiment of the present disclosure. FIG. 6 is a schematic layout diagram of another display panel according to an embodiment of the present disclosure. FIG. 7 is a schematic layout diagram of another display panel according to an embodiment of the present disclosure. FIG. 8 is a schematic layout diagram of another display panel according to an embodiment of the present disclosure. FIG. 9 is a schematic layout diagram of another display panel according to an embodiment of the present disclosure. FIG. 10 is a schematic layout diagram of another display panel according to an embodiment of the present disclosure.

As shown in FIGS. 4-10, along a direction Z perpendicular to a plane of the display panel 01, the first electrode RE overlaps with at least part of the threshold compensation transistor M1 and/or the gate initialization transistor M2. The array layer 22 includes a first power signal line DL1. The first power signal line DL1 may be configured to transmit a voltage PVDD. The first power signal line DL1 overlaps with at least part of the threshold compensation transistor M1 and/or the gate initialization transistor M2 along the direction Z perpendicular to the plane of the display panel 01.

In an embodiment, as shown in FIG. 4, in one pixel circuit 11, along the direction perpendicular to the plane of the display panel 01, the first electrode RE overlaps with the threshold compensation transistor M1, and the first power signal line DL1 overlaps with the gate initialization transistor M2.

In an embodiment, as shown in FIG. 5, in one pixel circuit 11, along the direction perpendicular to the plane of the display panel 01, the first power signal line DL1 overlaps with the threshold compensation transistor M1, and the first electrode RE overlaps with the gate initialization transistor M2.

In an embodiment, as shown in FIG. 6, in one pixel circuit 11, along the direction perpendicular to the plane of the display panel 01, the first electrode RE and the first power signal line DL1 together overlap with the threshold compensation transistor M1.

In an embodiment, as shown in FIG. 7, in one pixel circuit 11, along the direction perpendicular to the plane of the display panel 01, the first electrode RE and the first power signal line DL1 together overlap with the gate initialization transistor M2.

In an embodiment, as shown in FIG. 8, the display panel 01 includes pixel circuits 11. The pixel circuits 11 include a first pixel circuit 11A and a second pixel circuit 11B. Along the direction perpendicular to the plane of the display panel 01, the first electrode RE overlaps with the threshold compensation transistor M1 in the first pixel circuit 11A, and the first power signal line DL1 overlaps with the gate initialization transistor M2 in the second pixel circuit 11B.

In an embodiment, as shown in FIG. 9, the display panel 01 includes pixel circuits 11. The pixel circuits 11 include a first pixel circuit 11A and a second pixel circuit 11B. Along the direction perpendicular to the plane of the display panel 01, the first electrode RE overlaps with the threshold compensation transistor M1 in the first pixel circuit 11A, and the first power signal line DL1 overlaps with the threshold compensation transistor M1 in the second pixel circuit 11B.

In an embodiment, as shown in FIG. 10, the display panel 01 includes pixel circuits 11. The pixel circuits 11 include a first pixel circuit 11A and a second pixel circuit 11B. Along the direction perpendicular to the plane of the display panel 01, the first electrode RE overlaps with the gate initialization transistor M2 in the first pixel circuit 11A, and the first power signal line DL1 overlaps with the gate initialization transistor M2 in the second pixel circuit 11B.

That is, along the direction perpendicular to the plane of the display panel 01, the first electrode RE and the first power signal line DL1 may overlap with the transistor in one pixel circuit 11, or may respectively overlap with transistors in different pixel circuits 11.

Further, in one pixel circuit 11, the first electrode RE and the first power signal line DL1 may respectively overlap with different transistors, or may together overlap with a same transistor.

It can be understood that the light-emitting driving current provided by the pixel circuit 11 to the light-emitting device 12 is related to the gate potential of the driving transistor Td. It has been found through research that the external light exposure can cause an increase in the leakage current of the transistor. Since the threshold compensation transistor M1 and the gate initialization transistor M2 are both electrically connected to the gate of the driving transistor Td, when the external light is incident on either the threshold compensation transistor M1 or the gate initialization transistor M2, it can easily lead to a significant change in the gate potential of the driving transistor Td, resulting in poor stability of the light-emitting driving current provided by the pixel circuit 11 to the light-emitting device 12, easily causing the screen shaking of the display panel 01, and thus affecting the display quality.

In the embodiments of the present disclosure, the pixel circuit 11 includes a first transistor, the first transistor is electrically connected to the gate of the driving transistor Td, along the direction Z perpendicular to the plane of the display panel 01, the first electrode RE overlaps with at least part of the first transistor, and the first power signal line DL1 overlaps with at least part of the first transistor. The first transistor is the above-mentioned threshold compensation transistor M1 or gate initialization transistor M2.

As can be seen from the above analysis, the first electrode RE and the first power signal line DL1 are provided to overlap with at least part of the first transistor, thereby reducing the exposure of the first transistor to external ambient light, thus alleviating an influence of a large leakage current of the first transistor on the gate potential of the driving transistor Td, improving the poor brightness stability of the display panel 01, and thus improving the display effect.

At the same time, since the first electrode RE and the first power supply signal line DL1 are located in different layers, the first electrode RE and the first power supply signal line DL1 can cooperatively block the first transistor, thereby avoiding the space limitation of overlapping with the first transistor by a same layer, avoiding the external light at a relatively large angle from entering the first transistor, and thus further helping to solve the leakage current problem of the first transistor.

Moreover, the first electrode RE and the first power signal line DL1 may block the first transistors in different pixel circuits 11, thereby synchronous blocking the first transistors T1 in different pixel circuits 11, making it possible for the brightness changes of sub-pixels of different colors to be consistent, and thus avoiding the large-angle color cast of the display panel 01. In addition, the blocking degree of the first transistors T1 in different pixel circuits 11 by the first electrode RE and the first power signal line DL1 may also be flexibly adjusted as required, to meet different display requirements of the display panel 01.

In an embodiment of the present disclosure, as shown in FIG. 1, the display panel 01 includes sub-pixels P of different colors. The sub-pixel P includes the pixel circuit 11 and the light-emitting device 12 as described above. In the sub-pixels P of different colors, the light-emitting devices 12 emit light of different colors, but the structures of the pixel circuits 11 can be the same.

Along the direction perpendicular to the plane of the display panel 01, the first electrode RE and the first power signal line DL1 overlap with different first transistors. In an embodiment, the first electrode RE and the first power signal line DL1 overlap with the first transistors in the sub-pixels P of different colors.

For example, as shown in FIG. 9, the first transistor is the threshold compensation transistor M1 as an example, and the first pixel circuit 11A and the second pixel circuit 11B belong to sub-pixels of different colors. The first electrode RE overlaps with the threshold compensation transistor M1 in the first pixel circuit 11A, and the first power signal line DL1 overlaps with the threshold compensation transistor M1 in the second pixel circuit 11B.

In the embodiments of the present disclosure, the first transistor that cannot overlap with the first electrode RE may overlap with the first power supply signal line DL1, which is beneficial to avoiding that two first electrodes RE are too close to each other to overlap with different first transistors. While ensuring that the first transistor is blocked, it is also beneficial to preventing the occurrence of abnormal driving due to two adjacent first electrodes RE being too close to each other. In addition, the distance between two adjacent first electrodes RE is prevented from being too small, thereby reducing the requirement for etching precision of the two adjacent first electrodes RE, and thus reducing the process difficulty.

In addition, the layer of the first power signal line DL1 usually includes more wirings. The first electrode RE and the first power signal line DL1 are used to respectively overlap with different first transistors, thereby also avoiding excessive metal density of the layer of the first power signal line DL1, thereby reducing process difficulty and avoiding problems such as crosstalk and coupling of metal in a same layer.

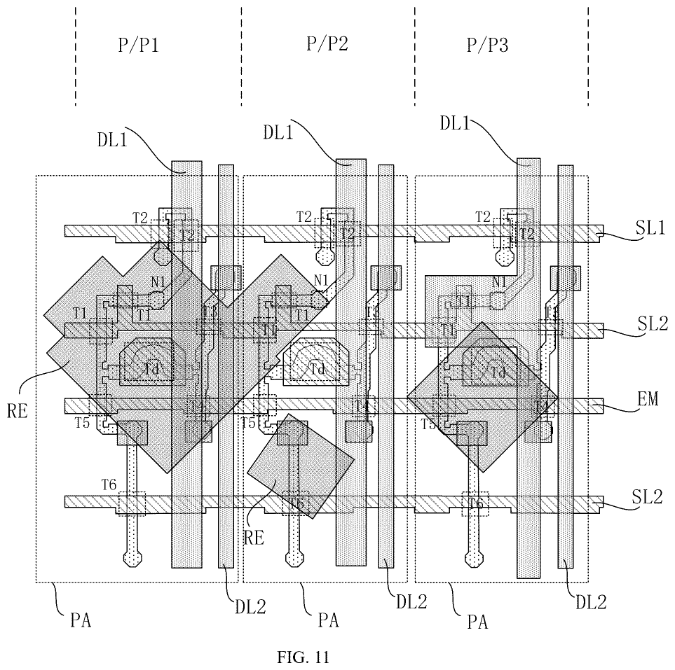

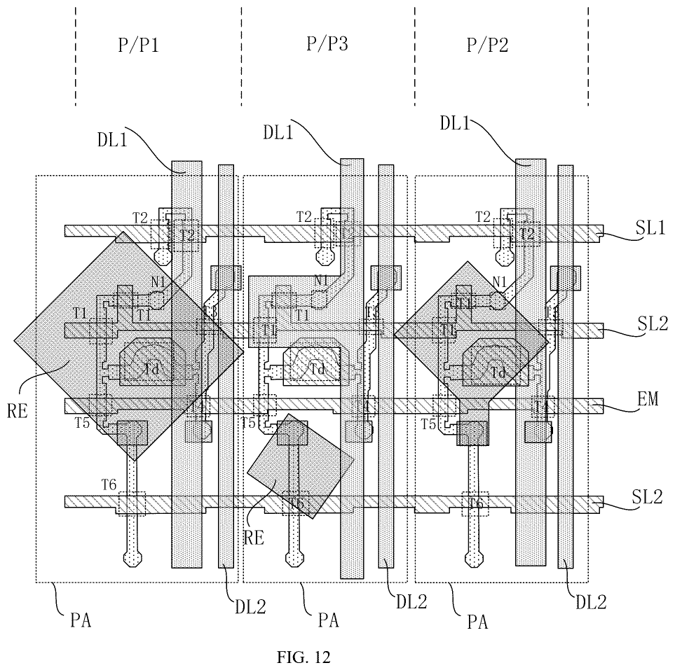

FIG. 11 is a schematic layout diagram of another display panel according to an embodiment of the present disclosure. FIG. 12 is a schematic layout diagram of another display panel according to an embodiment of the present disclosure.

In an embodiment of the present disclosure, as shown in FIG. 11, the sub-pixels P include a first sub-pixel P1, a second sub-pixel P2 and a third sub-pixel P3. The first sub-pixel P1, the second sub-pixel P2 and the third sub-pixel P3 may be sub-pixels of different colors. The sub-pixel P includes a pixel circuit PA. The pixel circuit PA includes a driving transistor Td and a first transistor T1. The first transistor T1 may be the threshold compensation transistor M1 in the foregoing embodiment.

Along the direction perpendicular to the plane of the display panel 01, the first electrode RE overlaps with the first transistor T1 in the first sub-pixel P1 and the first transistor T1 in the second sub-pixel P2, and the first power signal line DL1 overlaps with the first transistor T1 in the third sub-pixel P3.

In an embodiment, the first sub-pixel P1 is a blue sub-pixel, and the second sub-pixel P2 is one of a green sub-pixel and a red sub-pixel.

In an implementation, the first electrode RE overlaps with more first transistors T1, thereby being beneficial to reducing the number of first transistors T1 blocked by the first power signal line DL1, thus being beneficial to reducing the shape diversity of the first power signal line DL1, and further being beneficial to reducing the manufacturing difficulty of the first power signal line DL1.

In an embodiment, as shown in FIG. 11, the pixel circuit PA of the first sub-pixel P1 and the pixel circuit PA of the second sub-pixel P2 are adjacent to each other. In this case, the first transistors T1 of the first sub-pixel P1 and the second sub-pixel P2 may overlap with a same first electrode RE.

For example, the first sub-pixel P1 is a blue sub-pixel, the second sub-pixel P2 is a green sub-pixel, and the third sub-pixel P3 is a red sub-pixel. The first electrode RE of the first sub-pixel P1 overlaps with the first transistors T1 of the first sub-pixel P1 and the second sub-pixel P2.

In this case, the first electrode RE of the first sub-pixel P1 and the first electrode RE of the second sub-pixel P2 do not need to be provided too close to each other, thereby being beneficial to avoiding the driving abnormality caused by too close distance between the first electrode RE of the first sub-pixel P1 and the first electrode RE of the second sub-pixel P2.

Moreover, the first electrode RE may have a different area according to a different light-emitting efficiency of the sub-pixel. When the first sub-pixel P1 is a blue sub-pixel, the area of the first electrode RE of the first sub-pixel P1 is generally larger, and the first electrode RE of the first sub-pixel P1 may block the first transistor T1 of the first sub-pixel P1. In this case, appropriately increasing the first electrode RE of the first sub-pixel P1 can simultaneously block the first transistor T1 of the second sub-pixel P2, without modifying the first electrode RE of the second sub-pixel P2, thereby being beneficial to reducing the process difficulty.

In an embodiment, as shown in FIG. 12, the pixel circuit PA of the third sub-pixel P3 is located between the pixel circuit PA of the first sub-pixel P1 and the pixel circuit PA of the second sub-pixel P2. In this case, the first transistors T1 of the first sub-pixel P1 and the second sub-pixel P2 may overlap with different first electrodes RE.

For example, the first sub-pixel P1 is a blue sub-pixel, the second sub-pixel P2 is a red sub-pixel, and the third sub-pixel P3 is a green sub-pixel. The first electrode RE of the first sub-pixel P1 overlaps with the first transistor T1 of the first sub-pixel P1, and the first electrode RE of the second sub-pixel P2 overlaps with the first transistor T1 of the second sub-pixel P2.

In this way, the distance between the first electrode of the first sub-pixel P1 and the first electrode of the second sub-pixel P2 can be prevented from being too small, and the first electrode of the first sub-pixel P1 or the first electrode of the second sub-pixel P2 does not need to be formed to be too large, thereby being beneficial to saving the manufacturing cost.

It should be noted that, for convenience of illustrating the layout of the display panel, FIG. 11 and FIG. 12 only illustrate the channel layer, the gate layer of the transistor, the layer of the first power signal line DL1 and the first electrode RE.

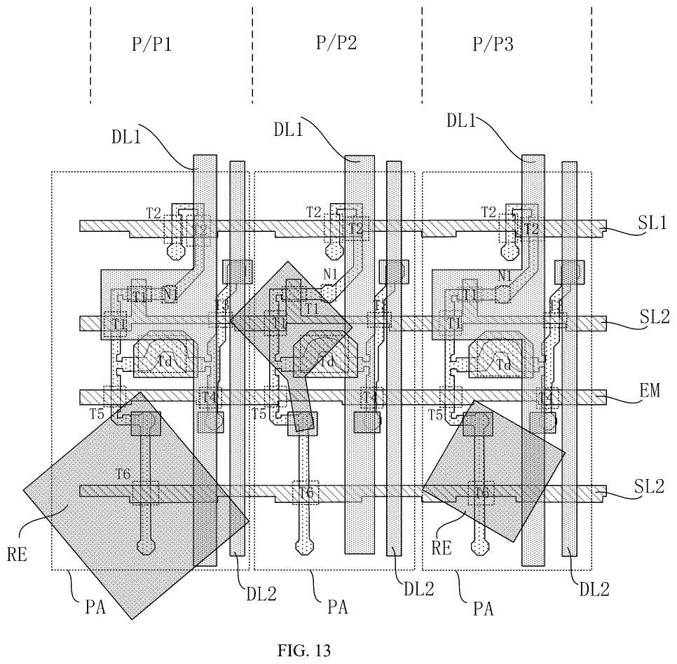

FIG. 13 is a schematic layout diagram of another display panel according to an embodiment of the present disclosure.

In another implementation of this embodiment of the present disclosure, as shown in FIG. 13, the sub-pixels P include a first sub-pixel P1, a second sub-pixel P2 and a third sub-pixel P3. The first sub-pixel P1, the second sub-pixel P2 and the third sub-pixel P3 may be sub-pixels of different colors.

In a direction perpendicular to the plane of the display panel 01, the first electrode RE overlaps with the first transistor T1 of the second sub-pixel P2, and the first power signal line DL1 overlaps with the first transistors T1 of the first sub-pixel P1 and the first transistors T1 of the third sub-pixel P3.

The first sub-pixel P1 is a blue sub-pixel, the second sub-pixel P2 is a green sub-pixel, and the third sub-pixel P3 is a red sub-pixel.

That is, along the direction perpendicular to the plane of the display panel 01, the first electrode RE overlaps with the first transistor T1 of the green sub-pixel, and the first power signal line DL1 overlaps with the first transistor T1 of the blue sub-pixel and the first transistor T1 of the red sub-pixel.

In an implementation, using the first power signal line DL1 to overlap with more first transistors T1 can reduce the number of the first transistors T1 blocked by the first electrode RE, thereby avoiding a case that the first electrodes RE in different sub-pixels P each have a relatively large area, thus improving a space utilization rate of the layer of the first electrode RE, and thus avoiding a distance between different first electrodes RE to be too small to cause driving abnormality. Moreover, preventing adjacent first electrodes RE from being too close to each other can also reduce a requirement for the etching precision of the first electrode RE, thereby being beneficial to reducing the manufacturing difficulty of the display panel 01. At the same time, it is not necessary to arrange more first electrodes RE to be large, which can prevent the metal density of the first electrode layer 231 from being too large, thereby ensuring the light transmittance of the display panel 01, and ensuring the normal operation of the light sensor inside the display panel 01 when the light sensor is integrated inside the display panel 01.

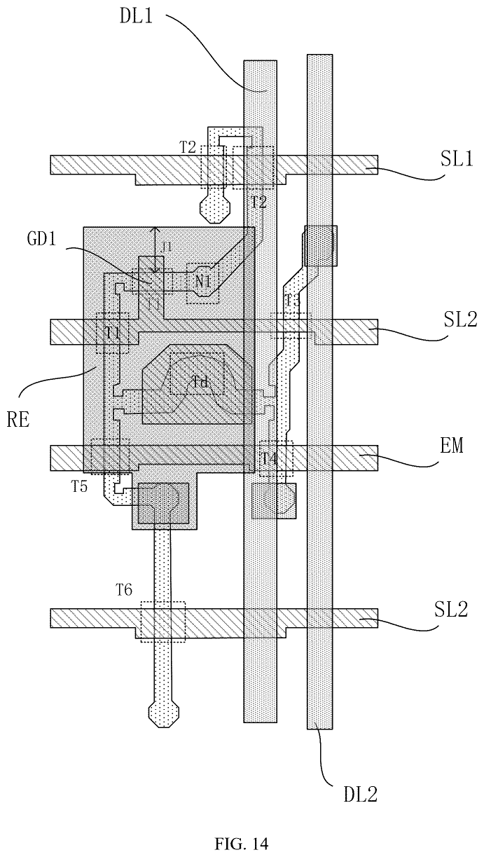

FIG. 14 is a schematic layout diagram of another display panel according to an embodiment of the present disclosure.

In an embodiment of the present disclosure, as shown in FIG. 14, the first transistor T1 includes a first channel portion GD1, and along the direction perpendicular to the plane of the display panel 01, a distance between an edge of the first electrode RE and a projection of the first channel portion GD1 onto the substrate 21 is J1, where 2.5 μm≤J1≤10.5 μm. J1 may be a minimum distance between an edge of the first electrode RE and a projection of the first channel portion GD1 onto the substrate 21.

In this way, the first electrode RE can block external light at different angles from entering the first channel portion GD1 of the first transistor T1, to meet different brightness requirements for the sub-pixels P.

In an embodiment, when 2.5 μm≤J1≤2.7 μm, the first electrode RE may block external light at 30° from entering the first channel portion GD1 of the first transistor T1. When 4.4 μm≤J1≤4.7 μm, the first electrode RE may block external light at 45° from entering the first channel portion GD1 of the first transistor T1. When 9.7 μm≤J1≤10.1 μm, the first electrode RE may block external light at 60° from entering the first channel portion GD1 of the first transistor T1.

It should be noted that when the first transistor T1 is a dual-gate transistor, all the channels of the first transistor T1 are the first channel portions GD1, and the first electrode RE may block the first channel portions GD1 of a same first transistor T1 to the same extent. For convenience of illustrating the layout of the display panel, FIG. 14 only illustrates the channel layer, the gate layer of the transistor, and the layer of the first power signal line DL1 and the first electrode RE.

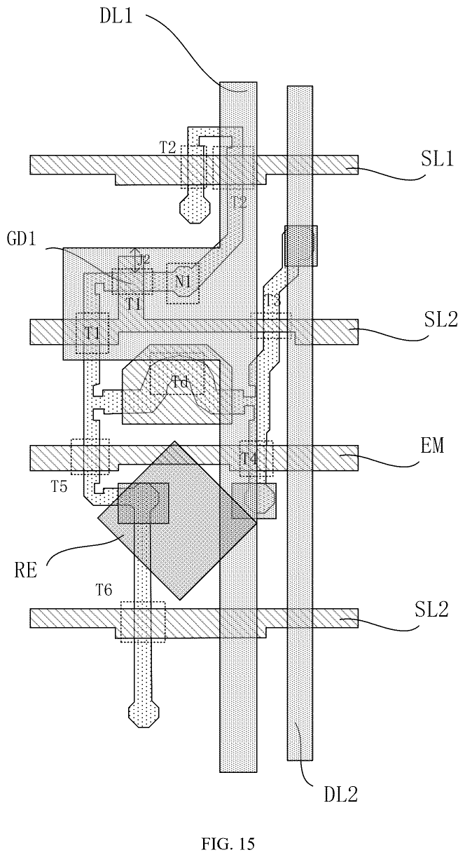

FIG. 15 is a schematic layout diagram of another display panel according to an embodiment of the present disclosure.

As shown in FIG. 15, in an embodiment of the present disclosure, the first transistor T1 includes a first channel portion GD1, and a distance between an edge of the first power signal line DL1 and a projection of the first channel portion GD1 onto the substrate 21 along the direction perpendicular to the plane of the display panel 01 is J2, where 1 μm≤J2≤7 μm. J2 may be a minimum distance between an edge of the first power signal line DL1 and a projection of the first channel portion GD1 onto the substrate 21.

In this way, the first power signal line DL1 can block external light at different angles from entering the first channel portion GD1 of the first transistor T1 to meet different brightness requirements of the sub-pixel P.

In an embodiment, 1 μm≤J2≤2 μm, for example, J2 may be 1.4 μm, 1.6 μm, 1.8 μm, and the like. The first power signal line DL1 may block external light at 30° from entering the first channel portion GD1 of the first transistor T1.

In an embodiment, 2 μm≤J2≤3 μm, for example, J2 may be 2.4 μm, 2.6 μm, 2.8 μm, and the like. The first power signal line DL1 may block external light at 45° from entering the first channel portion GD1 of the first transistor T1.

In an embodiment, 6 μm≤J2≤7 μm, for example, J2 may be 6.2 μm, 6.6 μm, 6.8 μm, and the like. The first power signal line DL1 may block external light at 60° from entering the first channel portion GD1 of the first transistor T1.

It should be noted that when the first transistor T1 is a dual-gate transistor, all the channels of the first transistor T1 are the first channel portions GD1, and the first power signal line DL1 may block the first channel portions GD1 of a same first transistor T1 to the same extent. For convenience of illustrating the layout of the display panel, FIG. 15 only illustrates the channel layer and the gate layer of the transistor, and the layer of the first power signal line DL1 and the first electrode RE.

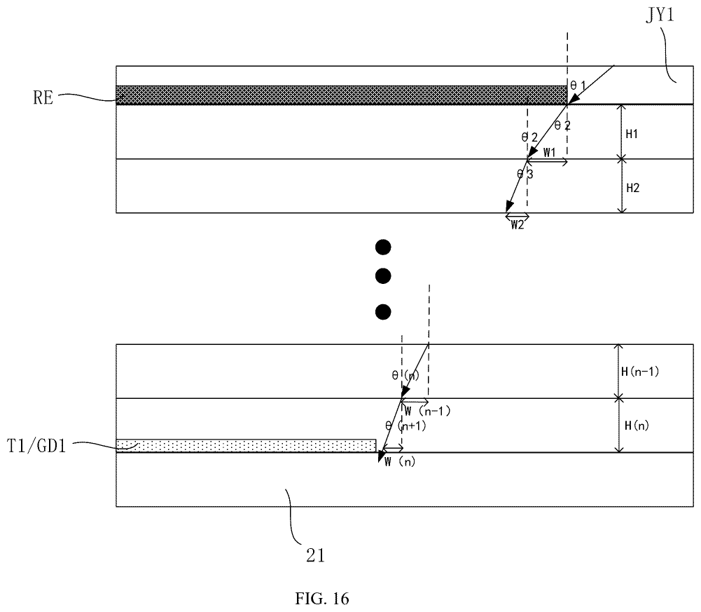

FIG. 16 is a schematic diagram of an optical path related to an embodiment of the present disclosure.

In the present disclosure, the working principle of the first electrode RE blocking the first channel portion GD1 may be as shown in FIG. 16. The distance between the edge of the first electrode RE and the projection of the first channel portion GD1 onto the substrate 21 is W. The incident light incident on the edge of the first electrode RE is at an angle θ1. A refractive index of an insulating layer JY1 overlapping with the edge of the first electrode RE is NO. The number of layers between the first electrode RE and the first channel portion GD1 is n, where n≥2. From the direction from the first electrode RE to the first channel portion GD1, the refractive index of each layer is N1, N2 · · · N (n), the thickness of each layer is H1, H2 · · · H (n), the refractive angle of each layer is θ2, θ3 · · · θ(n+1), and the offset of light between two adjacent layers is W1, W2 · · · W(n−1).

Where N0*sin θ1=N1*sin θ2, W1=H1*tan θ2; N1*sin θ2=N2*sin θ3, W2=H2*tan θ3; . . . ; N(n−1)*sin θ(n)=N(n)*sin θ(n+1), W(n)=H(n)*tan θ(n+1); W=W1+W2+ . . . +W(n).

In the present disclosure, the value of W can be controlled to adjust the value of θ1, thereby controlling an angle at which external light, blocked by the first electrode RE, enters the first transistor T1. Of course, the working principle is also applicable to the case of the first power signal line DL1 blocking the first transistor T1.

In an embodiment of the present disclosure, the blocking degrees of the first transistors T1 in the red sub-pixel, the green sub-pixel and the blue sub-pixel can be set to be same, that is, in the red sub-pixel, the green sub-pixel and the blue sub-pixel, the first electrode RE and/or the first power signal line DL1 may block external light at a same angle from entering the first channel portions of the first transistors T1 of these sub-pixels.

In this way, it is beneficial to making brightness changes of the red sub-pixel, the green sub-pixel, and the blue sub-pixel consistent, thereby helping to avoid color cast of the display panel 01.

The blocking degrees of the first transistors T1 in the red sub-pixel, the green sub-pixel and the blue sub-pixel may also be set to be different, that is, in the red sub-pixel, the green sub-pixel and the blue sub-pixel, the first electrode RE and/or the first power signal line DL1 may block external light at different angles from entering the first channel portions of the first transistors T1 of these sub-pixels. In this way, the brightness change degrees of the red sub-pixel, the green sub-pixel and the blue sub-pixel may be different, which is beneficial to achieving different display requirements of the display panel 01.

For example, the first electrode RE blocks the external light at 60° from entering the first transistors of the red sub-pixel and the blue sub-pixel, and the first power signal line DL1 blocks the external light at 30° from entering the first transistor of the green sub-pixel, thereby making the leakage current degree of the first transistor T1 in the green sub-pixel to be greater than the leakage current degree of the first transistor T1 in the red sub-pixel, and greater than the leakage current degree of the first transistor T1 in the blue sub-pixel, and thus the brightness change degree of the green sub-pixel is greater than the brightness change degree of the red sub-pixel, and greater than the brightness change degree of the blue sub-pixel. When the first transistor T1 is the gate initialization transistor, it can achieve a green effect of the display panel 01. When the first transistor T1 is a threshold compensation transistor, it can achieve a yellow display effect of the display panel 01.

For example, the first electrode RE blocks the external light at 60° from entering the first transistor of the blue sub-pixel, and the first power signal line DL1 blocks the external light at 30° from entering the first transistors of the red sub-pixel and the blue sub-pixel, thereby making the leakage current degree of the first transistor T1 in the green sub-pixel to be smaller than the leakage current degree of the first transistor T1 in the red sub-pixel, and smaller than the leakage current degree of the first transistor T1 in the blue sub-pixel, and thus the brightness change degree of the green sub-pixel is smaller than the brightness change degree of the red sub-pixel, and smaller than the brightness change degree of the blue sub-pixel. When the first transistor T1 is the gate initialization transistor, it can achieve the yellow effect of the display panel 01. When the first transistor T1 is a threshold compensation transistor, it can achieve a green display effect of the display panel 01.

It should be noted that, in this embodiment, the external light angle refers to an angle between the external light entering the display panel 01 and a direction perpendicular to the display panel.

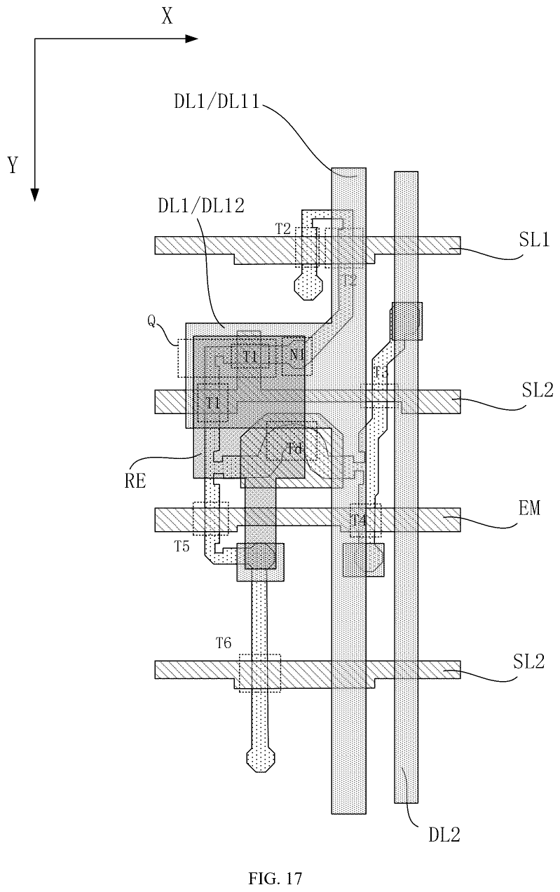

FIG. 17 is a schematic layout diagram of another display panel according to an embodiment of the present disclosure.

In an embodiment of the present disclosure, as shown in FIG. 1, the display panel 01 includes sub-pixels P of different colors, and the sub-pixel P includes the pixel circuit 11 and the light-emitting device 12 as described above. In the sub-pixels P of different colors, the light-emitting devices 12 emit light of different colors, but the structures of the pixel circuits 11 can be the same.

As shown in FIG. 17, along the direction perpendicular to the plane of the display panel 01, the first electrode RE and the first power signal line DL1 overlap with a same first transistor T1. It should be noted that FIG. 17 is illustrated by taking the first transistor T1 as the threshold compensation transistor M1 as an example, and in order to facilitate the layout of the display panel, FIG. 17 only illustrates the channel layer and the gate layer of the transistor, and the layer of the first power signal line DL1 and the first electrode RE.

That is, the first transistor T1 in a same sub-pixel P may overlap with a whole formed by the first electrode RE and the first power signal line DL1.

It can be seen from the above analysis that, in order to block the first transistor T1 to the same extent, along the direction perpendicular to the plane of the display panel 01, an edge of a projection of a blocking layer farther away from the channel of the first transistor T1 onto the plane of the channel needs to be farther away from the channel of the first transistor T1. That is, when the first transistor T1 is blocked to the same extent, when comparing a case of the first electrode RE being used alone to block the first transistor T1 and a case of the first power signal line DL1 being used alone to block the first transistor T1, a distance between an edge of a projection of the first electrode RE onto a plane of the channel and the channel of the first transistor T1 is greater than a distance between an edge of a projection of the first power signal line DL1 onto the plane of the channel and the channel of the first transistor T1.

Therefore, in order to block the external light at a larger angle from entering the first transistor T1, for example, at 60°, if the first electrode RE is used alone to block the first transistor T1, an area of the first electrode RE needs to be designed to be quite large, which would result in a small distance between adjacent first electrodes RE, to lead to difficult etching of the first electrode RE and difficult patterning of the first electrode RE in the process.

The inventor has found that there are quite many metal wires in the layer of the first power signal line DL1. If the first power signal line DL1 is used alone to block the first transistor T1, it would result in a high metal density in the layer of the first power signal line DL1, to lead to a complex manufacturing process of the first power signal line DL1, and on the other hand, easily increasing the coupling between the metal wires in a same layer, and thus affecting the signal transmission of the metal wires.

In view of this, in an embodiment of the present disclosure, the first electrode RE and the first power signal line DL1 are provided to together block a same first transistor T1. In this way, while blocking the first transistor T1, it can avoid the problem of too small distance between adjacent first electrodes RE and the problem of high metal density in the layer of the first power signal line DL1.

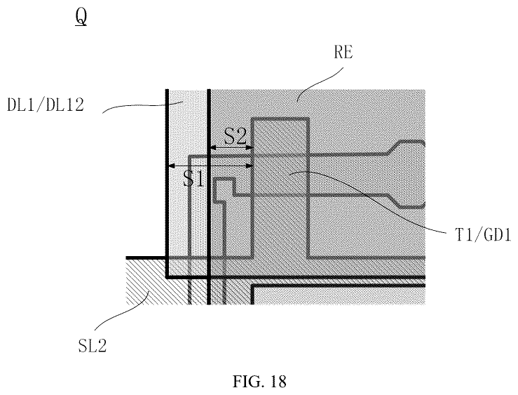

FIG. 18 is an enlarged view of region Q in FIG. 17.

Further referring to FIG. 17, in an embodiment of the present disclosure, the first power signal line DL1 includes a first portion DL11 and a second portion DL12. The first portion DL11 extends along the first direction Y, and the second portion DL12 is located at a side of the first portion DL11. The second portion DL12 overlaps with at least part of the first transistor T1 along the direction perpendicular to the plane of the display panel 01. The first direction Y may be a column direction of the display panel 01.

As shown in FIG. 18, the first transistor T1 includes a first channel portion GD1.

Along the direction perpendicular to the plane of the display panel 01, a minimum distance between an edge of the second portion DL12 and a projection of the first channel portion GD1 onto the substrate 21 is S1. The second portion DL12 refers to the second portion DL12 overlapping with the first channel portion GD1. A minimum distance between an edge of the first electrode RE and a projection of the first channel portion GD1 onto the substrate 21 is S2. The first electrode RE refers to the first electrode RE overlapping with the first channel portion GD1.

Where S1>S2.

In an embodiment of the present disclosure, if S1>S2, it is possible that the large-angle incident light that cannot be blocked by the first electrode RE can be blocked by the first power signal line DL1, which is beneficial to avoiding the large-angle external light from entering the first channel portion GD1 of the first transistor T1, so that it is possible that the first transistors T1 in the sub-pixels P of different colors are blocked to the same degree, then the brightness changes of the sub-pixels of different colors are consistent, thereby facilitating the implementation of no obvious color cast of the display panel 01.

In an embodiment, the first transistor T1 is of the green sub-pixel. Since the organic light-emitting material in the green sub-pixel has a higher light-emitting efficiency, a smaller light-emitting area can achieve a higher light-emitting efficiency. An area of the first electrode RE in the green sub-pixel is usually small. The first electrode RE and the first power signal line DL1 together overlap with the first transistor T1 in the green sub-pixel, so that the large-angle incident light that cannot be blocked by the first electrode RE can be blocked by the first power signal line DL1, which is beneficial to achieving the same blocking degree of the first transistors T1 in the green sub-pixel, the red sub-pixel and the blue sub-pixel under the large-angle incident light, thereby being beneficial to achieving no obvious color cast of the display panel 01.

In an embodiment of the present disclosure, with reference to FIG. 3 and FIG. 17, the array layer 22 includes a data line DL2, and the first power signal line DL1 and the data line DL2 are located in a same layer. It should be noted that, in FIG. 17, structures with a same filling pattern are located in a same layer.

That is, the first power signal line DL1 and the data line DL2 may be formed by a same material and a same process.

In the embodiments of the present disclosure, the first power signal line DL1 and the data line DL2 are provided in the same layer, so that the first power signal line DL1 can be manufactured while manufacturing the data line DL2, which is beneficial to simplifying the manufacturing process of the display panel 01 and thus reducing the manufacturing cost.

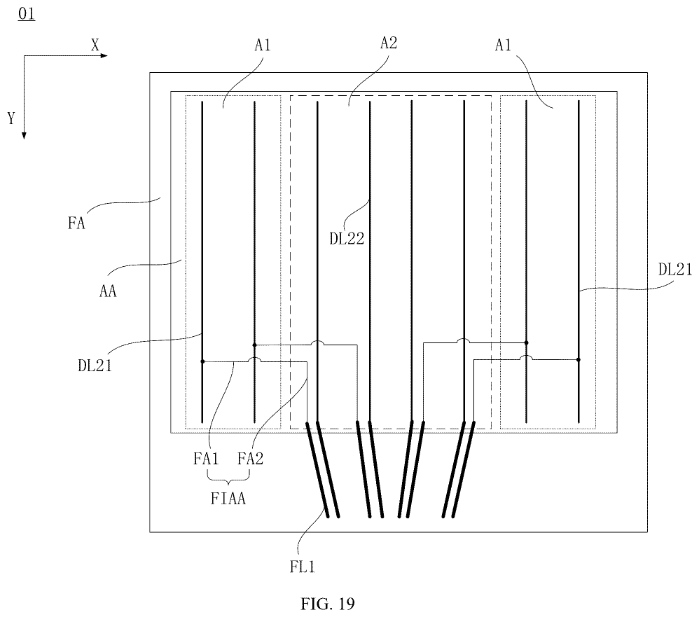

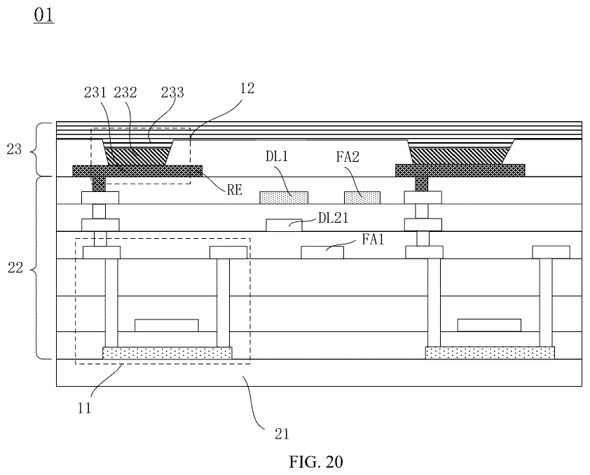

FIG. 19 is a schematic plan diagram of another display panel according to an embodiment of the present disclosure. FIG. 20 is a schematic cross-sectional view of the display panel shown in FIG. 19.

In an embodiment of the present disclosure, as shown in FIG. 19, the display panel 01 includes a display region AA and a non-display region NA surrounding the display region AA. The display region AA includes a first display region A1 and a second display region A2 adjacent to each other. The first display region A1 is located at a side of the second display region A2 close to an edge of the display panel 01.

The first display region A1 includes a first data line DL21 extending along the first direction Y. The non-display region NA includes a fan-out line FL1. The fan-out line FL1 may transmit the data voltage Vdata to the first data line DL21. The first data line DL21 is electrically connected to the fan-out line FL1 through a fan-out data line FIAA. The fan-out data line FIAA may extend from the first display region A1 to the second display region A2.

The fan-out data line FIAA includes a first line segment FA1 and a second line segment FA2. The second line segment FA2 and the first data line DL21 extend in the same direction. As shown in FIG. 20, the second line segment FA2 and the first data line DL21 are located in different layers, while the first power signal line DL1 and the second line segment FA2 are located in the same layer. The first power signal line DL1 and the second line segment FA2 may be formed by a same material and a same process.

In an embodiment, as shown in FIG. 20, the second line segment FA2 is located at a side of the first data line DL21 away from the substrate 21. That is, the first power signal line DL1 is located at a side of the first data line DL1 away from the substrate 21.

The first line segment FA1 may extend along the second direction X. The second direction X intersects with the first direction Y. The second direction X may be a row direction (an extending direction of a scan line) in the display panel 01, and the first line segment FA1 and the first data line DL21 are located in different layers.

In an embodiment, the first line segment FA1 is located at a side of the first data line DL21 close to the substrate 21. In some other embodiments, the first line segment FA1 may be in the same layer as the second line segment FA2, and then the first power signal line DL1 may be disconnected at the first line segment FA1. Since two adjacent first power signal lines DL1 may be connected through some connection lines, even if the first power signal line DL1 is disconnected at the first line segment FA1, it will not affect signal transmission on the first power signal line DL1.

In an embodiment of the present disclosure, the first data line DL21 is electrically connected to the fan-out line FL1 by the fan-out data line FIAA, so that the fan-out line FL1 does not need to be inclined to the first display region A1, thereby reducing an inclination degree of the fan-out line FL1 and reducing a frame width of the non-display region NA. Moreover, the extension length of the second line segment FA2 is generally less than the extension length of the first data line DL21, and the first power signal line DL1 is provided in the same layer as the second line segment FA2 and located in a different layer from the first data line DL21, thereby reducing the wiring density of the layer of the first power signal line DL1, and thus improving the space utilization rate of the layer of the first power signal line DL1.

It should be noted that, as shown in FIG. 19, the second display region A2 further includes a second data line DL22, and the second data line DL22 may be directly connected to the fan-out line FL1.

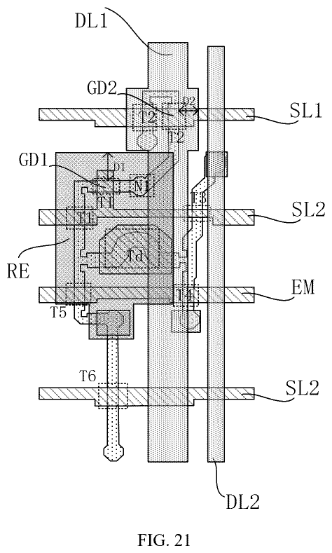

FIG. 21 is a schematic layout diagram of another display panel according to an embodiment of the present disclosure.

In an embodiment of the present disclosure, as shown in FIGS. 11-13, the pixel circuit PA further includes a second transistor T2. The first transistor T1 may be the threshold compensation transistor M1 in FIG. 2, and the second transistor T2 may be the gate initialization transistor M2 in FIG. 2. The second transistor T2 is electrically connected to the driving transistor Td and the first transistor T1. Both the first transistor T1 and the second transistor T2 may be electrically connected to the gate of the driving transistor Td at the first node N1. The second transistor T2 may be a dual-gate transistor.

As shown in FIG. 21, along the direction perpendicular to the plane of the display panel 01, the first electrode RE and/or the first power signal line DL1 overlaps with at least part of the second transistor T2.

That is, along the direction perpendicular to the plane of the display panel 01, the second transistor T2 may overlap with the first electrode RE, or may overlap with the first power signal line DL1, or may overlap with both the first electrode RE and the first power signal line DL1. It should be noted that FIG. 21 only illustrates that the first power signal line DL1 overlaps with the second transistor T2. For convenience of illustrating the layout of the display panel, FIG. 21 only illustrates the channel layer and the gate layer of the transistor, the layer of the first power signal line DL1 and the first electrode RE.

From the above analysis, it can be known that the second transistor T2 will also experience an increase in leakage current after being exposed to the external light. The second transistor T2 may be electrically connected to the gate of the driving transistor Td, thereby increasing the potential change of the gate of the driving transistor Td, resulting in poor stability of the light-emitting driving current provided by the pixel circuit 11 to the light-emitting device 12.

In the embodiments of the present disclosure, the first electrode RE and/or the first power signal line DL1 are provided to overlap with at least part of the second transistor T2, thereby reducing the exposure of the second transistor T2 to external ambient light, thus alleviating an influence of the large leakage current of the second transistor T2 on the gate potential of the driving transistor Td, improving the poor brightness stability of the display panel 01, and thus improving the display effect.

In an embodiment of the present disclosure, with reference to FIG. 1 and FIG. 21, the display panel 01 includes sub-pixels P of different colors. For a same sub-pixel P, along the direction perpendicular to the plane of the display panel 01, the first electrode RE overlaps with the first transistor T1, and the first power signal line DL1 overlaps with the second transistor T2.

In an embodiment of the present disclosure, for a same sub-pixel P, the first electrode RE is provided to overlap with the first transistor T1 and the first power signal line DL1 is provided to overlap with the second transistor T2, so that the first transistor T1 and the second transistor T2 may be individually blocked by using characteristics of different layers of the first electrode RE and the first power signal line DL1, thereby meeting different requirements for blocking the first transistor T1 and the second transistor T2.

Moreover, since the layer of the first power signal line DL1 is closer to the channel region of the transistor than the layer of the first electrode RE, it is easier for the first power signal line DL1 to block the external light at a relatively large angle from entering the second transistor T2, thereby improving the blocking capability of the second transistor T2.

In an embodiment, in a same sub-pixel P, the first electrode RE blocks the first transistor T1 to a degree the same as how the first power signal line DL1 blocks the second transistor T2.

For example, in a same sub-pixel P, the first electrode RE can block the external light at 45° from entering the first transistor T1, and the first power signal line DL1 can block the external light at 45° from entering the second transistor T2.

In an embodiment, in a same sub-pixel P, the first electrode RE blocks the first transistor T1 to a degree different from how the first power signal line DL1 blocks the second transistor T2.

For example, in a same sub-pixel P, the first electrode RE can block the external light at 30° from entering the first transistor T1, and the first power signal line DL1 can block the external light at 60° from entering the second transistor T2.

It should be noted that, in some other embodiments, for a same sub-pixel P, the first power signal line DL1 may overlap with the first transistor T1, and the first electrode RE may overlap with the second transistor T2.

Further referring to FIG. 21, in an embodiment of the present disclosure, the first transistor T1 includes a first channel portion GD1, and the second transistor T2 includes a second channel portion GD2. Along the direction perpendicular to the plane of the display panel 01, the first electrode RE overlaps with the first channel portion GD1 along the direction perpendicular to the plane of the display panel 01, and a minimum distance between an edge of the first electrode RE and a projection of the first channel portion GD1 onto the substrate 21 is D1; and the first power signal line DL1 overlaps with the second channel portion GD2, and a minimum distance between an edge of the first power signal line DL1 and a projection of the second channel portion GD2 onto the substrate 21 is D2.

Where D2<D1.

It can be known from the above embodiments that the distance between the first electrode RE and the first channel portion GD1 is greater than the distance between the first power signal line DL1 and the second channel portion GD2, then the capability of the first electrode RE to block the first channel portion GD1 is smaller than the capability of the first power signal line DL1 to block the second channel portion GD2.

In an embodiment of the present disclosure, if D2<D1, a range of the first electrode RE blocking the first channel portion GD1 may be greater than a range of the first power signal line DL1 blocking the second channel portion GD2, so that an external light angle that can be blocked by the first electrode RE from entering the first channel portion GD1 can be the same as an external light angle that can be blocked by the first power signal line DL1 from entering the second channel portion GD2, and thus making it possible for the first transistor T1 and the second transistor T2 to be blocked to a same extent, which is beneficial to synchronously blocking the first transistor T1 and the second transistor T2, and further beneficial to achieving a same brightness change of sub-pixels of different colors, and realizing no obvious color cast of the display panel.

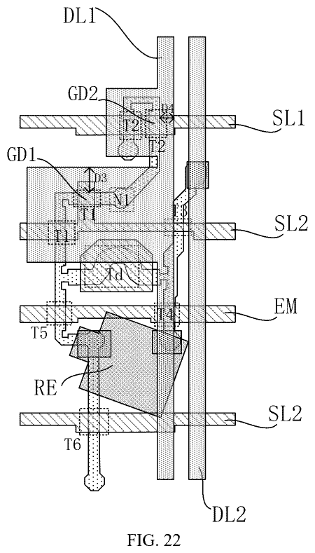

FIG. 22 is a schematic layout diagram of another display panel according to an embodiment of the present disclosure.

In an embodiment of the present disclosure, with reference to FIG. 1 and FIG. 22, the display panel 01 includes sub-pixels P of different colors. For a same sub-pixel P, the first power signal line DL1 overlaps with the first transistor T1 and the second transistor T2 along the direction perpendicular to the plane of the display panel 01.

In an embodiment, the first transistor T1 and the second transistor T2 in the same sub-pixel P overlap with a same first power signal line DL1.

It can be understood that in the pixel circuit 11 of a same sub-pixel P, the first transistor T1 and the second transistor T2 may be arranged relatively close to each other.

In an embodiment of the present disclosure, providing the first power signal line DL1 to overlap with the first transistor T1 and the second transistor T2 of a same sub-pixel P can reduce the difficulty of overlapping with the first transistor T1 and the second transistor T2 in the process, thereby reducing the manufacturing difficulty of the display panel 01.

Moreover, since the layer of the first power signal line DL1 is closer to a channel region of the transistor, it is easier for the first power signal line DL1 to block external light at a relatively large angle from entering the first transistor T1 and the second transistor T2, which is beneficial to improving the blocking capability of the first transistor T1 and the second transistor T2.

Further referring to FIG. 22, in an embodiment of the present disclosure, the first transistor T1 includes a first channel portion GD1, and the second transistor T2 includes a second channel portion GD2. In a same sub-pixel P, along the direction perpendicular to the plane of the display panel 01, the first power signal line DL1 overlaps with the first channel portion GD1, and a minimum distance between an edge of the first power signal line DL1 and a projection of the first channel portion GD1 onto the substrate 21 is D3; and the first power signal line DL1 overlaps with the second channel portion GD2, and a minimum distance between an edge of the first power signal line DL1 and a projection of the second channel portion GD2 onto the substrate 21 is D4.

Where D4<D3.

Since the first transistor T1 may be the threshold compensation transistor M1 in FIG. 2, and the second transistor T2 may be the gate initialization transistor M2 in FIG. 2. In combination with reference to FIG. 2, a first electrode of the second transistor T2 is electrically connected to the gate of the driving transistor Td, a second electrode of the second transistor T2 is electrically connected to a first reset signal line XL1, and a gate of the second transistor T2 is electrically connected to a first scan line SL1. Due to a low potential of the reset voltage Vref transmitted on the first reset signal line XL1, the leakage current of the second transistor T2 may cause a decrease in the gate potential of the driving transistor. A first electrode of the first transistor T1 is electrically connected to the gate of the driving transistor Td, a second electrode of the first transistor T1 is electrically connected to the first electrode of the driving transistor Td, and a gate of the first transistor T1 is electrically connected to a second scan line SL2. Due to a high potential of the first electrode of the driving transistor Td during the light-emitting phase, the leakage current of the first transistor T1 may cause an increase in the gate potential of the driving transistor Td.

In an embodiment of the present disclosure, if D4<D3, a range of the first power signal line DL1 blocking the first channel portion GD1 may be greater than a range of the first power signal line DL1 blocking the second channel portion GD2, so that an external light angle that can be blocked by the first power signal line DL1 from entering the first channel portion GD1 may be greater than an external light angle that can be blocked by the first power signal line DL1 from entering the second channel portion GD2, thereby making it possible for the leakage current of the first transistor T1 to be smaller than that of the second transistor T2, thus reducing the gate potential of the driving transistor Td and improving the brightness of the sub-pixels P.

It should be noted that, for convenience of illustrating the layout of the display panel, FIG. 22 only illustrates the channel layer and the gate layer of the transistor, and d the layer of the first power signal line DL1 and the first electrode RE.

In an embodiment, the same sub-pixel P is a green sub-pixel. That is, in the green sub-pixel, an external light angle that can be blocked by the first power signal line DL1 from entering the first channel portion GD1 may be greater than an external light angle that can be blocked by the first power signal line DL1 from entering the second channel portion GD2.

In this way, the brightness of the green sub-pixel can be improved, and since the green sub-pixel contributes greatly to the brightness of the display panel, thereby improving the brightness of the display panel 01.

Further referring to FIG. 2, the pixel circuit 11 further includes a third transistor T3, a fourth transistor T4, a fifth transistor T5, a sixth transistor T6 and a storage capacitor Cst. A first electrode of the third transistor T3 is electrically connected to the data line DL2, a second electrode of the third transistor T3 is electrically connected to the second electrode of the driving transistor Td, and a gate of the third transistor T3 is electrically connected to the second scanning line SL2. The third transistor T3 is used to transmit the data voltage Vdata to the driving transistor Td.

A first electrode of the fourth transistor T4 is electrically connected to the first power signal line DL1, a second electrode of the fourth transistor T4 is electrically connected to the second electrode of the driving transistor Td, and a gate of the fourth transistor T4 is electrically connected to the light-emitting control signal line EM. The fourth transistor T4 is used to transmit a voltage PVDD on the first power signal line DL1 to the driving transistor Td.

A first electrode of the fifth transistor T5 is electrically connected to the first electrode of the driving transistor Td, a second electrode of the fifth transistor T5 is electrically connected to the light-emitting device 12, and a gate of the fifth transistor T5 is electrically connected to the light-emitting control signal line EM. The fifth transistor T5 is used to transmit the light-emitting driving current to the light emitting device 12.

A first electrode of the sixth transistor T6 is electrically connected to the second reset signal line XL2, a second electrode of the sixth transistor T6 is electrically connected to the light emitting device 12, and a gate of the sixth transistor T6 is electrically connected to the second scan line SL2. The sixth transistor T6 is used to transmit the reset voltage Vref on the second reset signal line XL2 to the light emitting device 12, thereby completing the reset of the light emitting device 12.

One electrode plate of the storage capacitor Cst is electrically connected to the gate of the driving transistor Td, and the other electrode plate of the storage capacitor Cst is electrically connected to the first power signal line DL1.

A working process of driving the light emitting device 12 to emit light by the pixel circuit 11 may be the same as that in the related art, and details thereof will not be further described herein.

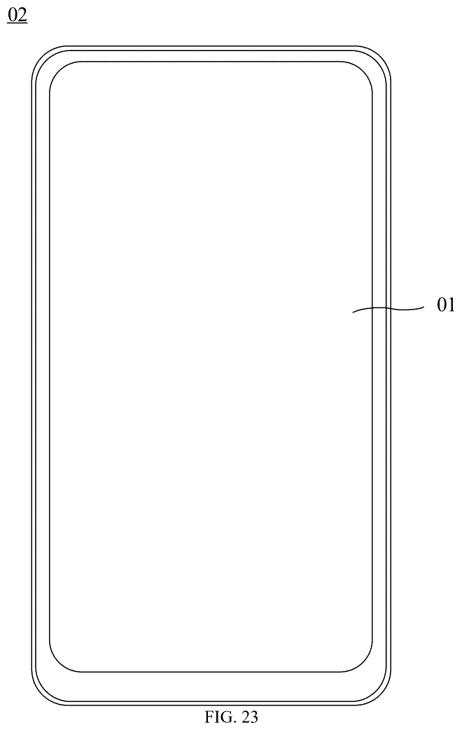

FIG. 23 is a schematic diagram of a display device according to an embodiment of the present disclosure.

An embodiment of the present disclosure further provides a display device 02. As shown in FIG. 23, the display device 02 includes the display panel 01 provided in the above embodiments. Exemplarily, the display device 02 may be an electronic device such as a mobile phone, a computer, a television, and a vehicle-mounted display, which is not specifically limited in the present disclosure.

In the display device 02, the first electrode RE and the first power signal line DL1 are provided to overlap with at least part of the first transistor T1, thereby reducing the exposure of the first transistor T1 to external ambient light, alleviating an influence of the large leakage current of the first transistor T1 on the gate potential of the driving transistor Td, improving the poor brightness stability of the display panel 01, and thus improving the display effect.

At the same time, since the first electrode RE and the first power supply signal line DL1 are located in different layers, the first electrode RE and the first power supply signal line DL1 can cooperatively block the first transistor T1, thereby avoiding the space limitation of overlapping with the first transistor T1 by a same layer, avoiding the external light at a relatively large angle from entering the first transistor, and thus further helping to solve the leakage current problem of the first transistor.

Moreover, the first electrode RE and the first power signal line DL1 may block the first transistors in different pixel circuits 11, thereby synchronously blocking the first transistors T1 in different pixel circuits 11, making it possible for the brightness changes of sub-pixels of different colors to be consistent, and thus avoiding the large-angle color cast of the display panel 01. In addition, the blocking degree of the first transistors T1 in different pixel circuits 11 by the first electrode RE and the first power signal line DL1 may be flexibly adjusted as required to meet different display requirements of the display panel 01.

The above descriptions are merely preferred embodiments of the present disclosure and are not intended to limit the present disclosure. It should be noted that any modifications, equivalent substitutions, improvements, and the like made within the spirit and principle of the present disclosure shall fall within the protection scope of the present disclosure.

What is claimed is:

1. A display panel, comprising:
a substrate;
an array layer;
an organic light-emitting layer; and
pixel circuits comprising a driving transistor and a first transistor, the driving transistor being electrically connected to the first transistor;
wherein the organic light-emitting layer comprises a first electrode layer, an organic layer, and a second electrode layer;
the first electrode layer comprises a first electrode; and
along a direction perpendicular to a plane of the display panel, the first electrode overlaps at least part of the first transistor; and the array layer comprises a first power signal line overlapping with at least part of the first transistor.

2. The display panel according to claim 1, wherein the display panel comprises sub-pixels of different colors, and the first electrode and the first power signal line overlap with different first transistors along the direction perpendicular to the plane of the display panel.

3. The display panel according to claim 2, wherein the sub-pixels comprise a first sub-pixel, a second sub-pixel, and a third sub-pixel; along the direction perpendicular to the plane of the display panel, the first electrode overlaps with the first transistor of the first sub-pixel and the first transistor of the second sub-pixel, and the first power signal line overlaps with the first transistor of the third sub-pixel.

4. The display panel according to claim 3, wherein the pixel circuit of the first sub-pixel and the pixel circuit of the second sub-pixel are adjacent to each other.

5. The display panel according to claim 4, wherein the first sub-pixel is a blue sub-pixel, and the second sub-pixel is one of a green sub-pixel or a red sub-pixel.

6. The display panel according to claim 2, wherein along the direction perpendicular to the plane of the display panel, the first electrode overlaps with the first transistor of a green sub-pixel, and the first power signal line overlaps with the first transistor of a blue sub-pixel and the first transistor of a red sub-pixel.

7. The display panel according to claim 1, wherein the display panel comprises sub-pixels of different colors, and along the direction perpendicular to the plane of the display panel, the first electrode and the first power signal line overlap with a same first transistor.

8. The display panel according to claim 7, wherein the first power signal line comprises a first portion and a second portion, and along the direction perpendicular to the plane of the display panel, the second portion overlaps with at least part of the first transistor; and
the first transistor comprises a first channel portion; a minimum distance between an edge of the second portion and a projection of the first channel portion onto the substrate is S1, and a minimum distance between an edge of the first electrode and a projection of the first channel portion onto the substrate is S2, where S1>S2.

9. The display panel according to claim 7, wherein the first transistor is of a green sub-pixel.

10. The display panel according to claim 1, wherein the display panel comprises a display region and a non-display region surrounding the display region, the display region comprises a first display region and a second display region adjacent to each other, the first display region is located at a side of the second display region close to an edge of the display panel, the first display region comprises a first data line; the non-display region comprises a fan-out line, the first data line is electrically connected to the fan-out line through a fan-out data line, the fan-out data line comprises a first line segment and a second line segment, the second line segment extends in a same direction as the first data line, the first data line and the second line segment are located in different layers, and the first power signal line and the second line segment are located in a same layer.

11. The display panel according to claim 1, wherein the pixel circuit further comprises a second transistor, the second transistor is electrically connected to the driving transistor and the first transistor, and the first electrode and/or the first power signal line overlap with at least part of the second transistor along the direction perpendicular to the plane of the display panel.

12. The display panel according to claim 11, wherein the display panel comprises sub-pixels of different colors, and for a same sub-pixel, along the direction perpendicular to the plane of the display panel, the first electrode overlaps with the first transistor and the first power signal line overlaps with the second transistor.

13. The display panel according to claim 12, wherein the first transistor comprises a first channel portion, and the second transistor comprises a second channel portion; and along the direction perpendicular to the plane of the display panel, a minimum distance between an edge of the first electrode and a projection of the first channel portion onto the substrate is D1, and a minimum distance between an edge of the first power signal line and a projection of the second channel portion onto the substrate is D2, where D2<D1.

14. The display panel according to claim 11, wherein the display panel comprises sub-pixels of different colors, and for a same sub-pixel, along the direction perpendicular to the plane of the display panel, the first power signal line overlaps with the first transistor and the second transistor.

15. The display panel according to claim 14, wherein the first transistor comprises a first channel portion, and the second transistor comprises a second channel portion; and along the direction perpendicular to the plane of the display panel, a minimum distance between an edge of the first power signal line and a projection of the first channel portion onto the substrate is D3, and a minimum distance between an edge of the first power signal line and a projection of the second channel portion onto the substrate is D4, where D4<D3.

16. The display panel according to claim 15, wherein the same sub-pixel is a green sub-pixel.

17. The display panel according to claim 11, wherein the first transistor is a threshold compensation transistor, and the second transistor is a gate initialization transistor.

18. The display panel according to claim 1, wherein the first transistor comprises a first channel portion, and a distance between an edge of the first electrode and a projection of the first channel portion onto the substrate along the direction perpendicular to the plane of the display panel is within a range from 2.5 μm to 10.5 μm.

19. The display panel according to claim 1, wherein the first transistor comprises a first channel portion, and a distance between an edge of the first power signal line and a projection of the first channel portion onto the substrate along the direction perpendicular to the plane of the display panel is within a range from 1 μm to 7 μm.

20. A display device, comprising a display panel, wherein the display panel comprises:
a substrate;
an array layer;
an organic light-emitting layer; and
pixel circuits comprising a driving transistor and a first transistor, the driving transistor being electrically connected to the first transistor;
wherein the organic light-emitting layer comprises a first electrode layer, an organic layer, and a second electrode layer;
the first electrode layer comprises a first electrode; and
along a direction perpendicular to a plane of the display panel, the first electrode overlaps with at least part of the first transistor; and the array layer comprises a first power signal line overlapping with at least part of the first transistor.
